(19) United States
(12) Patent Application Publication
(10) Pub. No.: US 2026/0142480 A1
(43) Pub. Date: May 21, 2026

(54) STATE OF CHARGE BALANCING METHOD FOR ENERGY-STORAGE MMC BASED ON CAPACITOR VOLTAGE CORRECTION

(71) Applicant: SOUTH CHINA UNIVERSITY OF TECHNOLOGY, Guangzhou City (CN)

(72) Inventors: Huangqing Xiao, Guangzhou City (CN); Qiluan Yang, Guangzhou City (CN); Qionghai Zhu, Guangzhou City (CN)

(21) Appl. No.: 19/450,313

(22) Filed: Jan. 15, 2026

Related U.S. Application Data
(63) Continuation of application No. PCT/CN2024/109693, filed on Aug. 5, 2024.

(30) Foreign Application Priority Data
Nov. 7, 2023 (CN) 202311474645.4

(51) Int. Cl. H02J 7/56; H02J 7/34; H02J 7/82; H02J 7/90; H02J 7/96; H02M 1/00; H02M 1/084; H03K 7/08

(52) U.S. Cl. CPC H02J 7/56; H02J 7/345; H02J 7/82; H02J 7/933; H02J 7/96; H02M 1/0009; H02M 1/007; H02M 1/084; H03K 7/08; H02J 2207/20; H02J 2207/50

(57) ABSTRACT

A state-of-charge balancing method for an energy-storage modular multilevel converter (MMC) based on capacitor voltage correction includes the following steps: acquiring key parameters of an energy-storage MMC such as states of charge of energy storage units and current directions of arms; calculating average values of states of charge (SOCs) of the phase units, the arms and three-phase energy storage units; calculating an inter-phase SOC imbalance degree, an inter-arm SOC imbalance degree, and an inter-submodule SOC imbalance degree, obtaining an inter-phase power deviation, an inter-arm power deviation, and an inter-submodule voltage deviation through proportional controllers, and calculating energy storage power reference values and corrected capacitor voltages of submodules; calculating a duty cycle of switching devices in a bidirectional DC/DC converter; and sorting the corrected capacitor voltages of the submodules, and determining to-be-inserted submodules according to a charging/discharging state of a submodule capacitor.

### TECHNICAL FIELD

The present disclosure relates to the technical field of state of charge (SOC) balancing control for energy storage units, and in particular, to a state of charge balancing method for an energy-storage modular multilevel converter (MMC) based on capacitor voltage correction.

### BACKGROUND

Power systems are facing significant challenges due to the increasing penetration of new energy. New energy power generation has characteristics of randomness and volatility and therefore it is necessary to integrate energy storage units to compensate for uncertainty in power output. Energy-storage modular multilevel converters (MMC) have thus emerged. However, due to a large number of energy storage submodules and unavoidable differences in losses and initial values among energy storage units, state of charge (SOC) becomes unbalanced, leading to over-charging or over-discharging of the energy storage units, and consequently affecting the system stability. Accordingly, balancing control is required for the SOC of the energy storage units in the energy-storage MMC.

A control strategy that achieves inter-phase, and upper and lower bridge arm SOC balancing through zero-sequence voltage injection and fundamental-frequency current injection involves complex calculation and is difficult to implement. Employing a conventional hierarchical SOC balancing control strategy to adjust energy storage power of each submodule requires a large number of controllers, results in low SOC balancing efficiency in a system, and limits a capacity utilization rate of the energy storage units. Therefore, a rapid SOC balancing method with simple calculation and straightforward control is urgently needed.

### SUMMARY OF THE INVENTION

An objective of the present disclosure is to overcome defects in the prior art such as numerous SOC balancing controllers and low system balancing efficiency, and provide a state of charge balancing method for an energy-storage modular multilevel converter (MMC) based on capacitor voltage correction. The control method utilizes a linear relationship between a voltage of an energy storage unit and a voltage of a submodule capacitor, achieves inter-submodule SOC balancing by correcting and equalizing a capacitor voltage of each submodule, and improves the SOC balancing efficiency, thereby enhancing a capacity utilization rate of the energy storage units.

The objective of the present disclosure may be achieved by employing the following technical solutions:

A state of charge balancing method for an energy-storage MMC based on capacitor voltage correction is provided. The state of charge balancing control method includes the following steps:
S1: acquiring current directions of arms and states of charge of energy storage units in an energy-storage MMC, acquiring modulation wave reference values of phase units and energy storage power set values of submodules, acquiring actual values of submodule capacitor voltages, submodule energy storage power, and submodule energy storage current, and acquiring a rated voltage of a submodule capacitor and a rated voltage of each submodule energy storage unit;
S2: calculating an average value of the SOC of the energy storage units in each arm, an average value of the SOC of the energy storage units in each phase unit, and an average value of the SOC of the energy storage units in all three phases;
S3: calculating an inter-phase SOC imbalance degree, an inter-arm SOC imbalance degree, and an inter-submodule SOC imbalance degree, obtaining an inter-phase power deviation, an inter-arm power deviation, and an inter-submodule voltage deviation through proportional controllers, and calculating energy storage power reference values and corrected capacitor voltages of the submodules;
S4: calculating a duty cycle of a switching device in a bidirectional DC/DC converter;
S5: sorting the corrected capacitor voltages of the submodules, and determining to-be-inserted submodules according to a charging/discharging state of each submodule capacitor.

Further, calculation formulas for the average value SOCᵣⱼ of the SOC of the energy storage units of each arm, the average value SOCⱼ of the SOC of the energy storage units of each phase unit, and the average value SOCₐᵥₑ of the SOC of the three-phase energy storage units are as follows:

$$\{ \begin{matrix}{SOC}_{rj} = \frac{1}{N} {\sum }_{i = 1}^{N} {SOC}_{rji} \\ {SOC}_{j} = \frac{1}{2 N} {\sum }_{i - 1}^{2 N} {SOC}_{rji} \\ {SOC}_{ave} = \frac{{SOC}_{a} + {SOC}_{b} + {SOC}_{c}}{3}\end{matrix}$$

$$\{ \begin{matrix}{SOC}_{rj} = \frac{1}{N} {\sum }_{i = 1}^{N} {SOC}_{rji} \\ {SOC}_{j} = \frac{1}{2 N} {\sum }_{i = 1}^{2 N} ( {SOC}_{pj} + {SOC}_{nj} ) \\ {SOC}_{ave} = \frac{{SOC}_{A} + {SOC}_{B} + {SOC}_{C}}{3}\end{matrix} ,$$

where N denotes the number of submodules in each arm, j=A, B, or C denotes one of the three phase units, r=p and n denotes one of an upper arm and a lower arm of each phase unit, i=1, 2, . . . , and N denotes an i^{th} submodule in the arm, namely, SOCᵣⱼᵢ denotes the SOC of the i^{th} submodule in an r arm of a phase j, SOC_{A} denotes an average value of the SOC of the energy storage units of the phase unit A, SOC_{B} denotes an average value of the SOC of the energy storage units of the phase unit B, and SOC_{C} denotes an average value of the SOC of the energy storage units of the phase unit C.

Further, calculation formulas for an inter-phase SOC imbalance degree ΔSOCⱼ, an inter-arm SOC imbalance degree ΔSOCᵣⱼ, and an inter-submodule SOC imbalance degree ΔSOCᵣⱼᵢ are as follows:

$$\{ \begin{matrix}Δ {SOC}_{j} = {SOC}_{ave} - {SOC}_{j} \\ Δ {SOC}_{rj} = {SOC}_{j} - {SOC}_{rj} \\ Δ {SOC}_{rji} = {SOC}_{rj} - {SOC}_{rji}\end{matrix}$$

where SOCₐᵥₑ denotes an average value of the SOC of the three-phase energy storage units, SOCⱼ denotes an average value of the SOC of the energy storage units of the phase j, SOCᵣⱼ denotes an average value of the SOC of the energy storage units of the r arm of the phase j, and SOCᵣⱼᵢ denotes the SOC of the i^{th} submodule in the r arm of the phase j.

Further, calculation formulas for a phase unit power deviation ΔP_{sc_j}, a arm power deviation ΔP_{sc_rj}, and a submodule voltage deviation ΔU_{sc_rji} are as follows:

$$\{ \begin{matrix}Δ {P}_{s {c}_{-} j} = {k}_{p h} Δ S O {C}_{j} \\ Δ {P}_{s {c}_{-} rj} = {k}_{a r m} Δ S O {C}_{rj} \\ Δ {U}_{s {c}_{-} rji} = {k}_{s m} Δ S O {C}_{rji}\end{matrix} ,$$

where kₚₕ, kₐᵣₘ, and kₛₘ denote proportional coefficients of an inter-phase SOC balancing controller, an inter-arm SOC balancing controller, and an inter-submodule SOC balancing controller, respectively, and ΔSOCⱼ, ΔSOCᵣⱼ, and ΔSOCᵣⱼᵢ denote the inter-phase SOC imbalance degree, the inter-arm imbalance degree, and the inter-submodule imbalance degree, respectively.

$${P}_{s c}^{ref}$$

Further, a calculation formula for the energy storage power reference values of the submodules is as follows:

$${P}_{s c}^{ref} = {P}_{s c}^{s e t} + Δ {P}_{sc \_ j} + Δ {P}_{sc \_ rj} ,$$

where

$${P}_{s c}^{s e t}$$

denotes the energy storage power set value of the submodules, ΔP_{sc_j} denotes the phase unit power deviation, and P_{sc_rj} denotes the arm power deviation.

Further, a calculation formula for the corrected capacitor voltage

$${U}_{s {m}_{-} rji}^{s o r t}$$

of the submodules is as follows:

$${U}_{s {m}_{-} rji}^{s o r t} = {U}_{s {m}_{-} rji} + Δ {U}_{s {c}_{-} rji} ,$$

where U_{sm_rji} denotes an actual value of the capacitor voltage of the i^{th} submodule in the r arm of the phase j, and ΔU_{sc_rji} denotes a voltage deviation of a corresponding submodule.

Further, a calculation formula for the reference value

$${I}_{L \_ rj}^{ref}$$

for an average value of energy storage current of the arms is as follows:

$${I}_{{L}_{-} rj}^{ref} = ( {K}_{PP} + \frac{{K}_{IP}}{s} ) ( {P}_{s c}^{ref} - {P}_{s {c}_{-} rj} ) ,$$

where K_{PP} and K_{IP} denote a proportional parameter and an integral parameter of an energy storage power controller, respectively, s denotes a Laplacian operator,

$${P}_{sc}^{ref}$$

denotes the energy storage power reference value of the submodules, P_{sc_rj} denotes an average value of energy storage power of the submodules in the arms, and an expression for P_{sc_rj} is as follows:

$${P}_{SC\_rj} = {\sum }_{i = 1}^{N} {P}_{SC\_rji} ,$$

where P_{sc_rji} denotes an actual value of the energy storage power of the i^{th} submodule in the r arm of the phase j. Through the aforementioned control law, the energy storage power of the submodules can be rapidly adjusted, so that the energy storage power of the submodules in each arm is identical.

Further, the bidirectional DC/DC converter employs complementary pulse width modulation (PWM) control, and a calculation formula for the duty cycle D of the switching devices is as follows:

$$D = ( {K}_{PC} + \frac{{K}_{IC}}{s} ) ( {I}_{L\_rj}^{ref} - {I}_{L\_rj} ) + {D}_{0} ,$$

where K_{PC} and K_{IC} denote a proportional parameter and an integral parameter of an energy storage current controller, respectively, s denotes a Laplacian operator,

$${I}_{L\_rj}^{ref}$$

denotes a reference value for an average value of energy storage current of the arms, I_{L_rj} denotes the average value of the energy storage current of the arms, D₀ denotes a feed-forward term of the duty cycle, and expressions for I_{L_rj} and D₀ are as follows:

$${I}_{L\_rj} = {\sum }_{i = 1}^{N} {I}_{L\_rji}$$

$${D}_{0} = \frac{{U}_{sc}^{*}}{{U}_{sm}^{*}} ,$$

where I_{L_rji} denotes an actual value of the energy storage current of the i^{th} submodule in the r arm of the phase j,

$${U}_{sc}^{*}$$

denotes the rated voltage of the energy storage unit of the submodule, and

$${U}_{sm}^{*}$$

denotes the rated voltage or the submodule capacitor. Through the aforementioned control law, the current can be rapidly regulated and clipped, thereby accelerating the SOC balancing; and under the complementary PWM mode, the switching device in the bidirectional DC/DC converter is controlled, so that the inter-phase SOC balancing and the inter-arm SOC balancing can be achieved.

Further, when nearest level modulation is employed, calculation formulas for the numbers Nₚₒₙ and Nₙₒₙ of submodules required to be inserted into the upper and lower arms of each phase unit are as follows:

$${N}_{non} = \frac{N}{2} + round ( \frac{{u}_{vj\_ref}}{{U}_{c\_sm}} )$$

$${N}_{pon} = N - {N}_{non} = \frac{N}{2} - round ( \frac{{u}_{vj\_ref}}{{U}_{c\_sm}} ) ,$$

where N denotes the number of submodules in each arm, u_{vj_ref} denotes a modulation wave reference value of the phase j, U_{c_sm} denotes the rated voltage of the submodule capacitor, and round(x) denotes an integer closest to x.

Further, the corrected capacitor voltages of the submodules are sorted in an ascending order, and the charging/discharging state of the submodule capacitor is determined according to the current direction of the arm. When the submodule capacitor is in the charging state, Nₚₒₙ and Nₙₒₙ submodules with the lowest voltage are inserted into the upper and lower arms, respectively; and when the submodule capacitor is in the discharging state, Nₚₒₙ and Nₙₒₙ submodules with the highest voltage are inserted into the upper and lower arms, respectively. Through the aforementioned control law, the inter-submodule SOC balancing can be achieved rapidly, and the capacity utilization rate of the energy storage units can be increased.

Compared with the prior art, the present disclosure has the following advantages and beneficial effects:

According to the present disclosure, based on the conventional hierarchical SOC balancing control, by utilizing a linear relationship between the voltage of the submodule capacitor and the voltage of the submodule energy storage unit in the energy-storage MMC, the inter-submodule SOC balancing is achieved by employing submodule capacitor voltage balancing control, thereby achieving the state of charge balancing of the energy-storage MMC. The balancing control significantly reduces the number of controllers for the bidirectional DC/DC converter, and can effectively increase the SOC balancing efficiency.

### BRIEF DESCRIPTION OF THE DRAWINGS

The drawings described here are used for further understanding of the present disclosure and constitute one part of the present disclosure. Schematic embodiments of the present disclosure and the description thereof are used to explain the present disclosure, and do not constitute an improper limitation to the present disclosure. In the drawings:

FIG. 1 is a flowchart of a state of charge balancing method for an energy-storage modular multilevel converter (MMC) based on capacitor voltage correction according to the present disclosure;

FIG. 2 is a topology diagram of an energy-storage MMC;

FIG. 3 is a control block diagram of a bidirectional DC/DC converter in an energy-storage MMC;

FIG. 4 is a control block diagram of balancing based on a corrected capacitor voltage in an energy-storage MMC;

FIG. 5 is a schematic diagram illustrating an SOC simulation waveform of submodules in an upper arm of a phase A in an energy-storage MMC employing a state of charge balancing method according to the present disclosure;

FIG. 6 is a schematic diagram illustrating an SOC simulation waveform of submodules in a lower arm of a phase A in an energy-storage MMC employing a state of charge balancing method according to the present disclosure;

FIG. 7 is a schematic diagram illustrating SOC simulation waveforms of an upper arm and a lower arm of a phase A in an energy-storage MMC employing a state of charge balancing method according to the present disclosure;

FIG. 8 is a schematic diagram illustrating SOC simulation waveforms of an upper arm and a lower arm of a phase B in an energy-storage MMC employing a state of charge balancing method according to the present disclosure;

FIG. 9 is a schematic diagram illustrating SOC simulation waveforms of phases A, B, and C in an energy-storage MMC employing a state of charge balancing method according to the present disclosure.

### DETAILED DESCRIPTION OF THE EMBODIMENTS

To make the purposes, technical solutions and advantages of embodiments of the present disclosure clearer, the technical solutions in the embodiments of the present disclosure are described clearly and completely in conjunction with drawings in the embodiments of the present disclosure. Apparently, the described embodiments are some embodiments of the present disclosure, not all embodiments. All other embodiments obtained by a person of ordinary skill in the art based on the embodiments of the present disclosure without creative efforts shall fall within the protection scope of the present disclosure.

### Embodiment 1

The present disclosure provides an energy-storage modular multilevel converter (MMC), where the energy-storage MMC includes six arms, each arm includes a plurality of energy storage submodules connected in series, an energy storage unit in each energy storage submodule is connected across a submodule capacitor through a bidirectional DC/DC converter. The six arms are divided into three groups, each group includes an upper arm and a lower arm, one upper arm and one lower arm form a phase unit, and consequently, the six arms constitute three phase units.

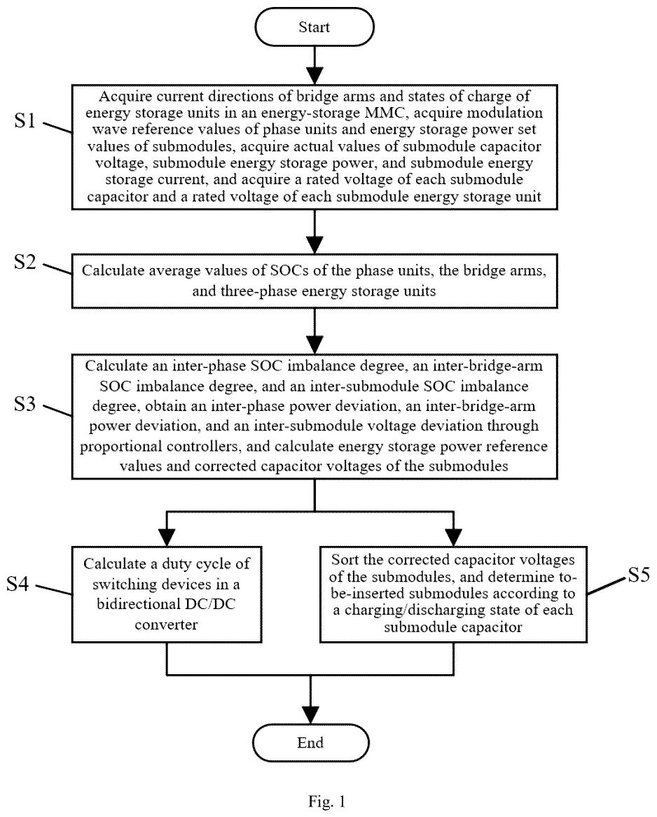

As shown in FIG. 1, the present embodiment discloses a state of charge balancing method for an energy-storage MMC based on capacitor voltage correction, including the following steps:
S1: acquire, for example, by using current sensors and energy storage unit management systems, current directions of arms and states of charge of energy storage units in an energy-storage MMC, acquire modulation wave reference values of the phase units and energy storage power set values of the submodules, acquire, for example, by using corresponding measurement instruments, actual values of submodule capacitor voltages, submodule energy storage power, and submodule energy storage current, and acquire a rated voltage of a submodule capacitor and a rated voltage of each submodule energy storage unit;
S2: calculating an average value of the SOC of the energy storage units in each arm, an average value of the SOC of the energy storage units in each phase unit, and an average value of the SOC of the energy storage units in all three phases;
calculation formulas for the average value SOCᵣⱼ of the SOC of the energy storage units of each arm, the average value SOCⱼ of the SOC of the energy storage units of each phase unit, and the average value SOCₐᵥₑ of the SOC of the three-phase energy storage units are as follows:

$$\{ \begin{matrix}S O {C}_{rj} = \frac{1}{N} {\sum }_{i = 1}^{N} S O {C}_{rji} \\ S O {C}_{j} = \frac{1}{2} ( S O {C}_{pj} + S O {C}_{nj} ) \\ S O {C}_{ave} = \frac{S O {C}_{A} + S O {C}_{B} + S O {C}_{C}}{3}\end{matrix} ,$$

where N denotes the number of submodules in each arm, j=A, B, or C denotes one of the three phase units, r=p and n denotes one of the upper and lower arms of each phase unit, i=1, 2, . . . , and N denotes an i^{th} submodule in the arm, namely, SOCᵣⱼᵢ denotes the SOC of the i^{th} submodule in an r arm of a phase j, SOC_{A} denotes the average value of the SOC of the energy storage units of the phase unit A, SOC_{B} denotes the average value of the SOC of the energy storage units of the phase unit B, and SOC_{C} denotes the average value of the SOC of the energy storage units of the phase unit C.

S3: calculate an inter-phase SOC imbalance degree, an inter-arm SOC imbalance degree, and an inter-submodule SOC imbalance degree, obtain an inter-phase power deviation, an inter-arm power deviation, and an inter-submodule voltage deviation through proportional controllers, and calculate energy storage power reference values and corrected capacitor voltages of the submodules;
calculation formulas for the inter-phase SOC imbalance degree ΔSOCⱼ, the inter-arm SOC imbalance degree ΔSOCᵣⱼ, and the inter-submodule SOC imbalance degree ΔSOCᵣⱼᵢ are as follows:

$$\{ \begin{matrix}Δ S O {C}_{j} = S O {C}_{ave} - S O {C}_{j} \\ Δ S O {C}_{rj} = S O {C}_{j} - S O {C}_{rj} \\ Δ S O {C}_{rji} = S O {C}_{rj} - S O {C}_{rji}\end{matrix} ,$$

where SOCₐᵥₑ denotes the average value of the SOCs of three-phase energy storage units, SOCⱼ denotes an average value of the SOC of the energy storage units of the phase j, SOCᵣⱼ denotes an average value of the SOC of the energy storage units of the r arm of the phase j, and SOCᵣⱼᵢ denotes the SOC of the i^{th} submodule in the r arm of the phase j.

To achieve the SOC balancing at each level, a phase unit power deviation ΔP_{sc_j} s, a arm power deviation ΔP_{sc_rj}, and a submodule voltage deviation ΔU_{sc_rji} need to be calculated, and calculation formulas are as follows:

$$\{ \begin{matrix}Δ {P}_{sc\_j} = {k}_{ph} Δ SO {C}_{j} \\ Δ {P}_{sc\_rj} = {k}_{arm} Δ SO {C}_{rj} \\ Δ {U}_{sc\_rji} = {k}_{sm} Δ SO {C}_{rji}\end{matrix} ,$$

where kₚₕ, kₐᵣₘ, and kₛₘ denote proportional coefficients of an inter-phase SOC balancing controller, an inter-arm SOC balancing controller, and an inter-submodule SOC balancing controller, respectively, and ΔSOCⱼ, ΔSOCᵣⱼ, and ΔSOCᵣⱼᵢ denote the inter-phase SOC imbalance degree, the inter-arm imbalance degree, and the inter-submodule imbalance degree, respectively.

To achieve the inter-phase SOC balancing and the inter-arm SOC balancing, the phase unit power deviation and the arm power deviation need to be added to energy storage power set values of the submodules to obtain the energy storage power reference values

$${P}_{sc}^{ref}$$

or the submodules, and a calculation formula is as follows:

$${P}_{sc}^{ref} = {P}_{sc}^{set} + Δ {P}_{sc\_j} + Δ {P}_{sc\_rj} ,$$

where

$${P}_{sc}^{set}$$

denotes the energy storage power set value of each submodule, ΔP_{sc_j} denotes the phase unit power deviation, and ΔP_{sc_rj} denotes the arm power deviation.

To achieve the inter-submodule SOC balancing, the inter-submodule voltage deviation is required to be added to the capacitor voltage of each submodule to obtain the corrected capacitor voltage

$${U}_{sm\_rji}^{sort}$$

of each submodule, anu a calculation formula is as follows:

$${U}_{sm \_ rji}^{s o r t} = {U}_{s {m}_{-} rji} + Δ {U}_{s {c}_{-} rji} ,$$

where U_{sm_rji} denotes an actual value of the capacitor voltage of the i^{th} submodule in the r arm of the phase j, and ΔU_{sc_rji} denotes a voltage deviation of a corresponding submodule.

S4: calculate a duty cycle of switching devices in the bidirectional DC/DC converter, and generate a corresponding PWM signal, where the PWM signal directly drives the switching device in the DC/DC converter, thereby regulating the energy storage power of each arm.

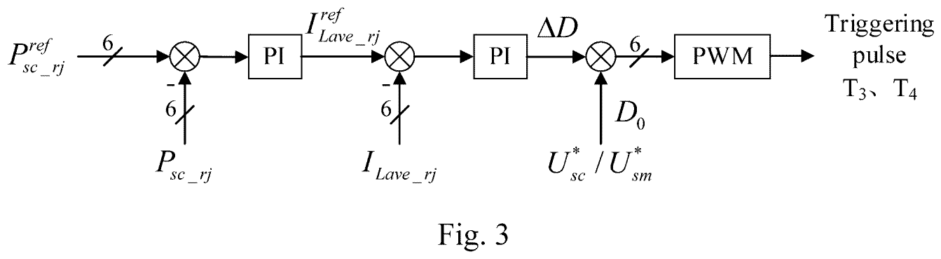

The bidirectional DC/DC converter employs complementary pulse width modulation (PWM) control. A control block diagram is shown in FIG. 3. A calculation formula for the duty cycle D of the switching devices is as follows:

$$D = ( {K}_{PC} + \frac{{K}_{IC}}{s} ) ( {I}_{L \_ rj}^{ref} - {I}_{L \_ rj} ) + {D}_{0} ,$$

where K_{PC} and K_{IC} denote a proportional parameter and an integral parameter of an energy storage current controller, respectively, s denotes a Laplacian operator,

$${I}_{{L}_{-} rj}^{ref}$$

denotes a reference value for an average value of energy storage current of the arms, I_{L_rj} denotes an average value of the energy storage current of the arms, D₀ denotes a feed-forward term of the duty cycle, and expressions for I_{L_rj} and D₀ are as follows:

$${I}_{{L}_{-} rj} = {\sum }_{i = 1}^{N} {I}_{{L}_{-} rji}$$

$${D}_{0} = \frac{{U}_{sc}^{*}}{{U}_{sm}^{*}} ,$$

where I_{L_rji} denotes an actual value of the energy storage current of the i^{th} submodule in the r arm of the phase j,

$${U}_{s c}^{*}$$

denotes the rated voltage of the energy storage unit of the submodule, and

$${U}_{s m}^{*}$$

denotes the rated voltage or the submodule capacitor.

A calculation formula of the reference value

$${I}_{{L}_{-} rj}^{r e f}$$

for the average value of the energy storage current of the arms is as follows:

$${I}_{{L}_{-} rj}^{ref} = ( {K}_{P P} + \frac{{K}_{IP}}{s} ) ( {P}_{s c}^{ref} - {P}_{sc \_ rj} ) ,$$

where K_{PP} and K_{IP} denote a proportional parameter and an integral parameter of an energy storage power controller, respectively, s denotes a Laplacian operator,

$${P}_{s c}^{ref}$$

denotes an energy storage power reference value of the submodules, P_{sc_rj} denotes an average value of the energy storage power of the submodules in the arms, and an expression for P_{sc_rj} is as follows:

$${P}_{{SC}_{-} rj} = {\sum }_{i = 1}^{N} {P}_{{SC}_{-} rji} ,$$

where P_{sc_rj} denotes an actual value of the energy storage power of the i^{th} submodule in the r arm of the phase j.

S5: sort the corrected capacitor voltages of the submodules, and determine to-be-inserted submodules according to a charging/discharging state of each submodule capacitor, where the to-be-inserted submodules are determined according to a sorting result of the capacitor voltages of the submodules and a current polarity of each arm, and by combining the nearest level modulation theory, corresponding triggering pulses are generated to drive the switching devices on the MMC side, thereby achieving the SOC balancing control.

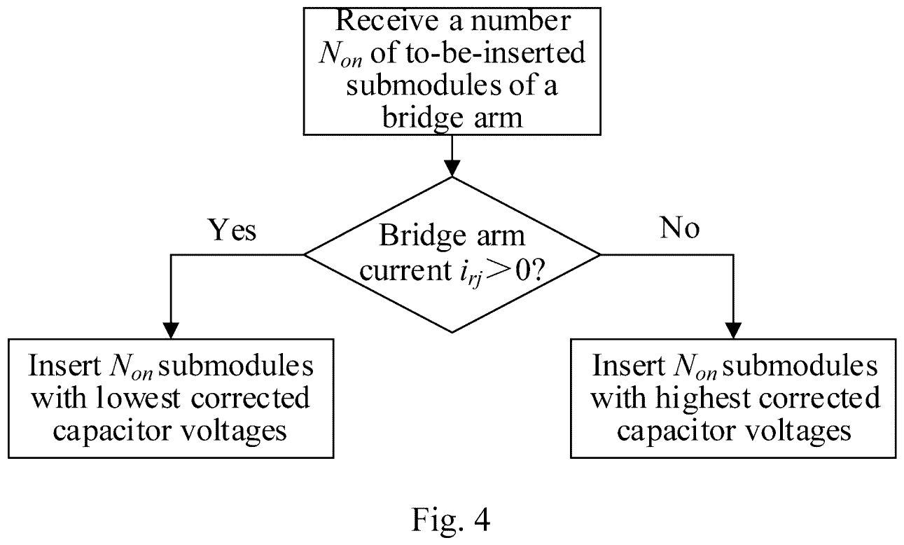

A control block diagram of balancing based on the corrected capacitor voltage is shown in FIG. 4, and the to-be-inserted submodules are determined according to the sorting result of the capacitor voltages of the submodules and the current polarity of each arm. When the submodule capacitor is in the charging state, namely, when the submodule capacitor is charged by the current of the arm, Nₚₒₙ and Nₙₒₙ submodules with the lowest voltage are inserted into the and lower arms, respectively; and when the submodule capacitor is in the discharging state, namely, when the submodule capacitor is discharged by the current of the arm, Nₚₒₙ and Nₙₒₙ submodules with the highest voltage are inserted into the upper and lower arms, respectively.

The term “insert” refers to activating or enabling selected submodules in the arms, thereby bringing them into an active operating state and allowing current to flow through them. When a submodule is inserted, the submodule transitions from a bypassed state (where its capacitor is isolated from the arm current) to an inserted state (where its capacitor is connected in series within the arm). By selectively inserting or deactivating submodules, the control system can balance the SOC among submodules.

When the nearest level modulation is employed, calculations for the numbers Nₚₒₙ and Nₙₒₙ of the submodules required to be inserted into the upper and lower arms in each phase unit are as follows:

$${N}_{n o n} = \frac{N}{2} + round ( \frac{{u}_{vj \_ ref}}{{U}_{{c}_{-} s m}} )$$

$${N}_{p o n} = N - {N}_{n o n} = \frac{N}{2} - round ( \frac{{u}_{{vj}_{-} ref}}{{U}_{c \_ sm}} ) ,$$

where N denotes the number of submodules in each arm, u_{vj_ref} denotes a modulation wave reference value of the phase j, j=A, B, or C denotes three phase units, U_{c_sm} denotes the rated voltage of the submodule capacitor, and round(x) denotes an integer closest to x.

### Embodiment 2

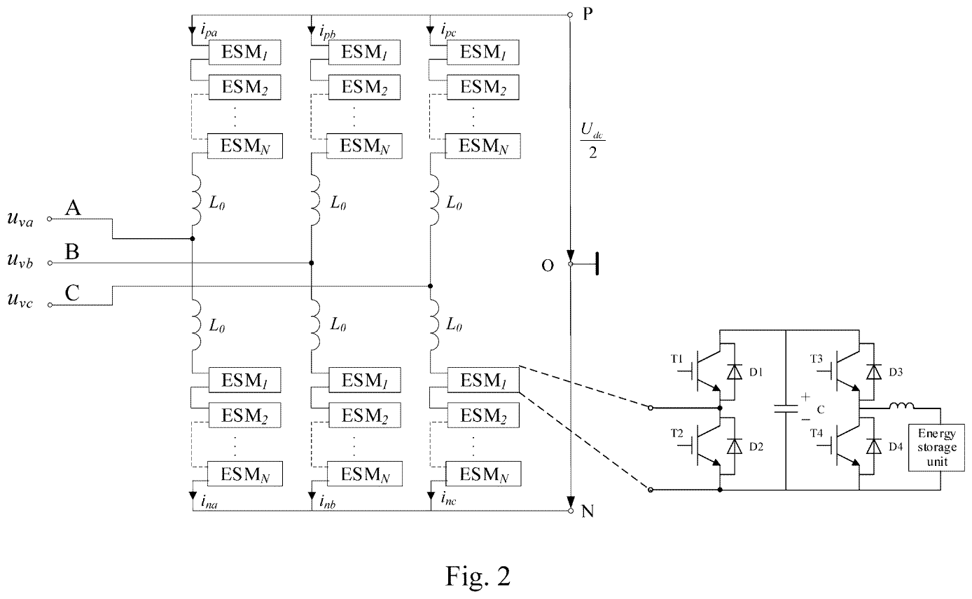

Based on the state of charge balancing method for the energy-storage MMC based on the capacitor voltage correction disclosed in Embodiment 1, the present embodiment employs a topology structure of the energy-storage MMC as shown in FIG. 2 for simulation validation. A two-terminal power transmission system based on a five-level energy-storage MMC is constructed. Converter stations on both ends have a rated capacity of 1.5 MW, and energy storage systems have a rated capacity of 0.36 MW. Specific parameters are shown in Table 1. Stages of charge (SOC) of energy storage units are balanced by using the balancing method disclosed in the present disclosure. Each arm of the energy-storage MMC in FIG. 2 includes a plurality of energy storage submodules connected in series, and energy storage units in each energy storage submodule are connected in parallel with a submodule capacitor through a bidirectional DC/DC converter. T₁, T₂, and Cₛₘ form a half-bridge submodule, T₃, T₄, and L_{sc} form the bidirectional DC/DC converter, and a super-capacitor Csc is connected to the submodule.

TABLE 1
Simulation Parameter Table

| Parameter | Numerical value | |
|---|---|---|
| Grid-side AC rated voltage uₛ | 10 | kv |
| DC rated voltage U_{dc} | 5 | kv |
| AC system frequency f | 50 | Hz |
| Number of submodules in each arm N | 4 | |
| Arm reactance L₀ | 4 | mH |
| Submodule capacitance Cₛₘ | 10 | mF |
| Super-capacitance | 2 | F |
| Energy storage inductance L_{sc} | 1 | mH |
| Switching frequency fₛ | 5 | kHz |

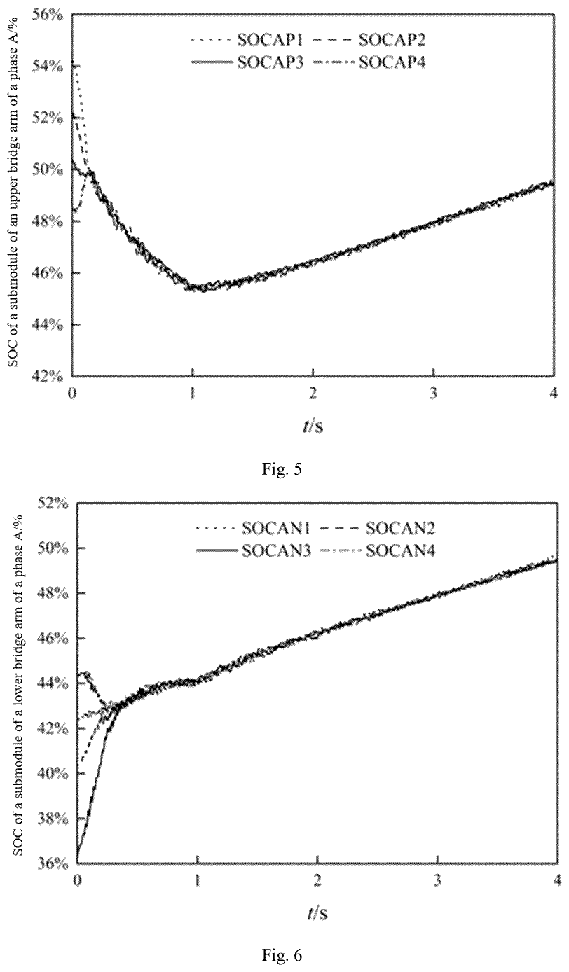

Further, at an initial instant, the SOCs of the submodules in an upper arm of a phase A are obtained as 54.0%, 52.0%, 50.0%, and 48.0%, respectively, and the SOCs of the submodules in a lower arm of the phase A are obtained as 42.0%, 40.0%, 36.0%, and 44.0%, respectively. The SOCs of the submodules in the upper arm of a phase B are balanced, all at 46%, and the SOCs of the submodules in the lower arm of the phase B are also balanced, all at 40%. The SOCs of the submodules in a phase C are balanced, all at 48%. At time t=1 s, the energy storage unit undergoes a step change in power from injecting 0.6 p.u. to outputting 0.8 p.u. Corresponding SOC simulation waveforms are shown in FIG. 5 to FIG. 9.

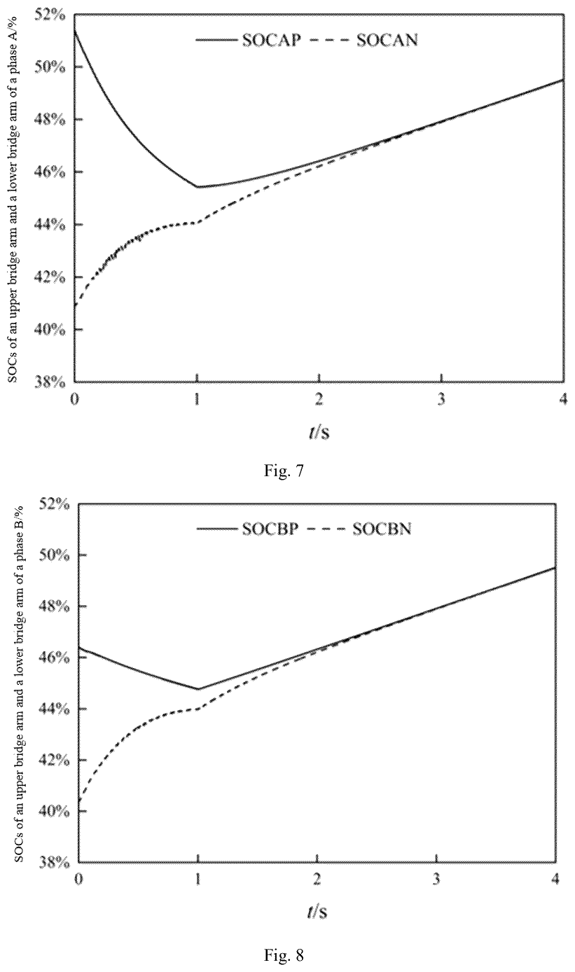

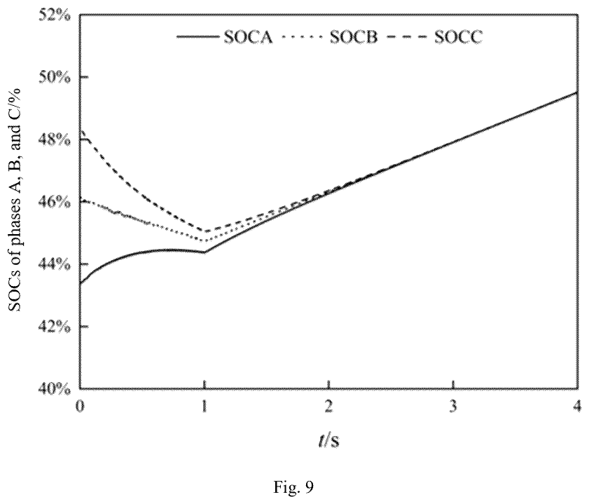

FIG. 5 shows an SOC waveform of each submodule in the upper arm of the phase A. FIG. 6 shows an SOC waveform of each submodule in the lower arm of the phase A. FIG. 7 shows SOC waveforms of both the upper and lower arms of the phase A. FIG. 8 shows SOC waveforms of both the upper and lower arms of the phase B. FIG. 9 shows SOC waveforms of all three phases A, B, and C. As can be seen from simulation results, the SOC is balanced across phases, between the arms of the phases A and B, and among the submodules in the phase A. The state of charge balancing method for the energy-storage MMC based on the capacitor voltage correction features not only a simple structure with fewer controllers for ease of implementation but also a high balancing speed. The method further increases a capacity utilization rate of the energy storage units and improves the stability of the energy-storage MMC.

The above embodiments are preferred embodiments of the present disclosure, but the embodiments of the present disclosure are not limited by the above embodiments, and any other changes, modifications, substitutions, combinations, simplification, etc. made without departing from the spirit and principle of the present disclosure should all be equivalent replacement methods, and should all be included in the protection scope of the present disclosure.

1. A method for balancing a state of charge (SOC) of energy storage units in an energy-storage modular multilevel converter (MMC), comprising:
providing the energy-storage MMC, the energy-storage MMC comprising three phase units, each phase unit comprising an upper arm and a lower arm, each arm comprising a plurality of energy storage submodules connected in series, each energy storage submodule comprising an energy storage unit, a submodule capacitor, and a bidirectional DC/DC converter being electrically couple the energy storage unit to the submodule capacitor;
acquiring a current direction of each arm and a SOC of each energy storage unit in the energy-storage MMC, acquiring a modulation wave reference value of each phase unit and an energy storage power set value of each submodule, acquiring an actual value of a voltage of each submodule capacitor voltage, an actual value of an energy storage power of each submodule, and an actual value of an energy storage current of each submodule, and acquiring a rated voltage of each submodule capacitor and a rated voltage of each energy storage unit;
calculating an average value of the SOC of the energy storage units in each arm, an average value of the SOC of the energy storage units in each phase unit, and an average value of the SOC of the energy storage units in all the three phase units;
calculating an inter-phase SOC imbalance degree, an inter-arm SOC imbalance degree, and an inter-submodule SOC imbalance degree, obtaining an inter-phase power deviation, an inter-arm power deviation, and an inter-submodule voltage deviation through proportional controllers, and calculating an energy storage power reference value of each submodule and a corrected voltage of each submodule capacitor;
calculating a duty cycle of a switching device in the bidirectional DC/DC converter, a calculation formula for the duty cycle D of the switching device being as follows:
$$D = ( {K}_{P C} + \frac{{K}_{I C}}{s} ) ( {I}_{{L}_{-} r j}^{ref} - {I}_{{L}_{-} r j} ) + {D}_{0} ,$$
wherein K_{PC} and K_{IC} denote a proportional parameter and an integral parameter of an energy storage current controller, respectively, s denotes a Laplacian operator,
$${I}_{L \_ rj}^{ref}$$
denotes a reference value for an average value of energy storage current of the arms, I_{L_rj} denotes the average value of the energy storage current of the arms, D₀ denotes a feed-forward term of the duty cycle, and expressions for I_{L_rj} and D₀ are as follows:
$${I}_{L \_ rj} = {{\sum }^{N}}_{i = 1} {I}_{{L}_{-} rji}$$
$${D}_{0} = \frac{{U}_{sc}^{*}}{{U}_{sm}^{*}} ,$$
wherein j denotes one of the three phase units A, B, and C, r denotes one of the upper arm p and the lower arm n of each phase unit, i denotes an i^{th} submodule of the submodules 1, 2, . . . , and N in each arm, namely, I_{L_rji} denotes an actual value of the energy storage current of the i^{th} submodule in a arm r of the phase unit j,
$${U}_{s c}^{*}$$
denotes the rated voltage of each energy storage unit, and
$${U}_{s m}^{*}$$
denotes the rated voltage of each submodule capacitor;
a calculation formula for the reference value
$${I}_{L\_rj}^{r e f}$$
for the average value of the energy storage current of the arms is as follows:
$${I}_{L\_rj}^{r e f} = ( {K}_{P P} + \frac{{K}_{I P}}{S} ) ( {P}_{s c}^{r e f} - {P}_{sc\_r j} ) ,$$
wherein K_{PP} and K_{IP} denote a proportional parameter and an integral parameter of an energy storage power controller, respectively, s denotes a Laplacian operator,
$${P}_{s c}^{r e f}$$
denotes an energy storage power reference value of the submodules, P_{sc_rj} denotes an average value of the energy storage power of the submodules in the arms, and an expression for P_{sc_rj} is as follows:
$${P}_{SC \_r j} = {\sum }_{i = 1}^{N} {P}_{SC\_rji} ,$$
wherein P_{sc_rji} denotes an actual value of the energy storage power of the i^{th} submodule in the arm r of the phase unit j;
based on the duty cycle of the switching devices in the bidirectional DC/DC converter, controlling the switching device in the bidirectional DC/DC converter by employing complementary pulse width modulation (PWM), to balance the inter-phase SOC and the inter-arm SOC; and
inserting a first number of submodules, selected from the plurality of the submodules of the upper arm, into the upper arm and a second number of submodules, selected from the plurality of the submodules of the lower arm, into the lower arm according to the corrected voltage and a charging or discharging state of each submodule capacitor, to balance the inter-submodule SOC, thereby balancing the SOC of the energy-storage MMC.

2. The method of claim 1, wherein calculation formulas for the average value SOCᵣⱼ of the SOC of the energy storage units in each arm, the average value SOCⱼ of the SOC of the energy storage units in each phase unit, and the average value SOCₐᵥₑ of the SOC of the energy storage units in all the three phase units are as follows:
$$\{ \begin{matrix}S O {C}_{r j} = \frac{1}{N} {\sum }_{j = 1}^{N} S O {C}_{rji} \\ S O {C}_{j} = \frac{1}{2} ( S O {C}_{p j} + S O {C}_{n j} ) \\ S O {C}_{ave} = \frac{S O {C}_{A} + S O {C}_{B} + S O {C}_{C}}{3}\end{matrix} ,$$
wherein N denotes a number of the submodules in each arm, j denotes one of the three phase units A, B, and C, r denotes one of the upper and lower arms p and n of each phase unit, i denotes the i^{th} submodule of the submodules 1, 2, . . . , and N in each arm, namely, SOCᵣⱼᵢ denotes the SOC of the energy storage units of the i^{th} submodule in the arm r of the phase unit j, SOC_{A} denotes the average value of the SOC of the energy storage units in the phase unit A, SOC_{B} denotes the average value of the SOC of the energy storage units in the phase unit B, and SOC_{C} denotes the average value of the SOC of the energy storage units in the phase unit C.

3. The method of claim 1, wherein calculation formulas for the inter-phase SOC imbalance degree ΔSOCⱼ, the inter-arm SOC imbalance degree ΔSOCᵣⱼ, and the inter-submodule SOC imbalance degree ΔSOCᵣⱼᵢ are as follows:
$$\{ \begin{matrix}Δ S O {C}_{j} = S O {C}_{a v e} - S O {C}_{j} \\ Δ S O {C}_{rj} = S O {C}_{j} - SO {C}_{rj} \\ Δ S O {C}_{r j i} = S O {C}_{rj} - SO {C}_{r j i}\end{matrix} ,$$
wherein SOCₐᵥₑ denotes the average value of the SOC of the energy storage units in all the three phase units, j denotes one of the three phase units A, B, and C, r denotes one of the upper and lower arms p and n of each phase unit, i denotes the i^{th} submodule of the submodules 1, 2, . . . , and N in each arm, namely, SOCⱼ denotes the average value of the SOC of the energy storage units in the phase unit j, SOCᵣⱼ denotes the average value of the SOC of the energy storage units in the arm r of the phase unit j, and SOCᵣⱼᵢ denotes the SOC of the i^{th} submodule in the arm r of the phase unit j;
a phase unit power deviation ΔP_{sc_j}, a arm power deviation ΔP_{sc_rj}, and a submodule voltage deviation ΔU_{sc_rji} are calculated according to following calculation formulas:
$$\{ \begin{matrix}Δ {P}_{sc\_j} = {k}_{p h} Δ S O {C}_{j} \\ Δ {P}_{sc\_rj} = {k}_{a r m} Δ S O {C}_{r j} \\ Δ {U}_{sc\_rji} = {k}_{s m} Δ S O {C}_{r j i}\end{matrix} ,$$
wherein kₚₕ, kₐᵣₘ, and kₛₘ denote proportional coefficients of an inter-phase SOC balancing controller, an inter-arm SOC balancing controller, and an inter-submodule SOC balancing controller, respectively, and ΔSOCⱼ, ΔSOCᵣⱼ, and ΔSOCᵣⱼᵢ denote the inter-phase SOC imbalance degree, the inter-arm SOC imbalance degree, and the inter-submodule SOC imbalance degree, respectively;
the phase unit power deviation and the arm power deviation are added to the energy storage power set value of each submodule to obtain the reference value
$${P}_{s c}^{r e f}$$
for the energy storage power of each submodule, and a calculation formula is as follows:
$${P}_{s c}^{r e f} = {P}_{s c}^{s e t} + Δ {P}_{sc\_j} + Δ {P}_{sc\_rj} ,$$
wherein
$${P}_{s c}^{s e t}$$
denotes the energy storage power set value of each submodule, ΔP_{sc_j} denotes the phase unit power deviation, and ΔP_{sc_rj} denotes the arm power deviation;
the inter-submodule voltage deviation is added to each submodule capacitor voltage, to obtain the corrected capacitor voltage
$${U}_{sm\_rji}^{r e v}$$
of the submodules, and a calculation formula is as follows:
$${U}_{sm\_rji}^{r e v} = {U}_{sm\_rji} + Δ {U}_{sc\_rji} ,$$
wherein U_{sm_rji} denotes the actual value of the voltage of the capacitor of the i^{th} submodule in the arm r of the phase unit j, and ΔU_{sc_rji} denotes a voltage deviation of a corresponding submodule.

4. The method of claim 1, wherein inserting the first number and the second number of the submodules according to the corrected voltage and the charging or discharging state of each submodule capacitor comprises:
sorting corrected voltages of capacitors of the submodules in an ascending order to determine a lowest voltage and a highest voltage;
determining the charging or discharging state of each submodule capacitor according to the current directions of the arms;
inserting Nₚₒₙ and Nₙₒₙ submodules with the lowest voltage into the upper and lower arms, respectively, when the submodule capacitor is in the charging state; and
inserting Nₚₒₙ and Nₙₒₙ submodules with the highest voltage into the upper and lower arms, respectively, when the submodule capacitor is in the discharging state.

5. The method of claim 4, wherein when nearest level modulation is employed, calculation formulas for the numbers Nₚₒₙ and Nₙₒₙ of the submodules required to be inserted into the upper and lower arms of each phase unit are as follows:
$$\begin{matrix}{N}_{n o n} = \frac{N}{2} + r o u n d ( \frac{{u}_{vj\_ref}}{{U}_{c \_ sm}} ) \\ {N}_{p o n} = N - {N}_{n o n} = \frac{N}{2} - r o u n d ( \frac{{u}_{vj \_ ref}}{{U}_{c \_ sm}} ) ,\end{matrix}$$
wherein N denotes the number of submodules in each arm, u_{vj_ref} denotes a modulation wave reference value of the phase unit j, j denotes one of the three phase units A, B, and C, U_{c_sm} denotes the rated voltage of each submodule capacitor, and round(x) denotes an integer closest to x.
